(19) United States
(12) Patent Application Publication
(10) Pub. No.: US 2008/0121956 A1
(43) Pub. Date: May 29, 2008

(54) SEMICONDUCTOR DEVICE HAVING FERROELECTRIC MEMORY CELL AND METHOD FOR FABRICATING THE SAME

(75) Inventor: Hiroyuki KANAYA, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/942,339

(22) Filed: Nov. 19, 2007

(30) Foreign Application Priority Data
Nov. 29, 2006 (JP) 2006-322038

(51) Int. Cl. H01L 27/00; H01L 21/00

(52) U.S. Cl. 257/295; 438/3; 257/E21.001

(57) ABSTRACT

According to an aspect of the invention, there is provided, a semiconductor device having a ferroelectric memory cell, comprising a semiconductor substrate, a transistor being formed on the semiconductor substrate, an inter-layer insulator being formed over the transistor to cover the transistor, a ferroelectric capacitor including a lower electrode formed over the inter-layer insulator, a ferroelectric film and a upper electrode stacked in order, and a hydrogen barrier film covering a surface including the side-wall of the ferroelectric capacitor, wherein at least a portion of a tilt of a side-wall of the lower electrode, the tilt of the side-wall of the lower electrode having an angle to an bottom surface of the lower electrode, is more gradual than a tilt of a side-wall of the upper electrode and a side-wall of the ferroelectric film continuing to the side-wall of the lower electrode.

### CROSS REFERENCE TO RELATED APPLICATION

This application is based upon and claims the benefit of priority from the prior Japanese Patent Application No. JP2006-322038, filed Nov. 29, 2006; the entire contents of which are incorporated herein by reference.

### FIELD OF THE INVENTION

The present invention is related to a semiconductor device including a ferroelectric memory cell and a method for fabricating the semiconductor device including the ferroelectric memory cell.

### DESCRIPTION OF THE BACKGROUND

Conventionally, a ferroelectric random access memory called as a FeRAM which is a semiconductor device memorizing data in non volatile by using a ferroelectric capacitor, have been well known. A chain-type FeRAM, in a FeRAM group, is constituted of a plurality of unit cells, each unit cell including a transistor and a ferroelectric capacitor being connected each other in parallel, being connected each other in series as a cell array block. The ferroelectric capacitor is formed of a lower electrode, a ferroelectric film and an upper electrode stacked in order over the semiconductor substrate covered with insulator.

The chain-type FeRAM has a capability of miniaturization of a unit cell by sharing a diffusion layer between adjacent transistors in the cell array block and using a COP (Capacitor On Plug) structure of the ferroelectric capacitor.

In the COP structure, a contact plug is embedded in an inter-layer insulator on the semiconductor substrate having the transistor. The ferroelectric capacitor is formed on the contact plug. In this case, a pair of the two ferroelectric capacitors is formed accompanying with a common lower electrode connecting to the diffusion layer via a contact plug. The ferroelectric film on the common lower electrode is not necessary to separate. However, the pair of the upper electrode being connected to the ferroelectric film is separated each other so as to constitute each cell, respectively.

As the chain-type FeRAM has been demanded for higher integration, miniaturization of the cell has been preceded. For example, Japanese Patent Publication (Kokai) No. 2001-257320 discloses a structure having a fine cell mentioned below.

For example, the ferroelectric capacitor including the lower electrode, the ferroelectric film and the upper electrode stacked in order, a pair of the two ferroelectric capacitors has the common lower electrode and an individual upper electrode, respectively. Further, a space between the upper electrodes in the pair of the two ferroelectric capacitors and a space between the adjacent pairs are processed by one dry etching step. As a result, a semiconductor device having a sharp tilt in the dry-etched side-wall is formed.

The semiconductor device disclosed is effective as shrinking the cell, however, an outer side-wall of the pair of the two ferroelectric capacitors is a structure with a sharp tilt. Accordingly, when a hydrogen barrier film having a film thickness with necessary of protecting the ferroelectric film from hydrogen is formed on the lower portion of the side-wall, the hydrogen barrier film on the upper electrode is remarkably thick. Accordingly, when an opening is formed in the upper hydrogen barrier film for a contact, lowering a yield of formation the contact as a problem is generated.

### SUMMARY OF THE INVENTION

According to an aspect of the invention, there is provided, A semiconductor device having a ferroelectric memory cell, comprising, a semiconductor substrate, a transistor being formed on the semiconductor substrate, an inter-layer insulator being formed over the transistor to cover the transistor, a ferroelectric capacitor including a lower electrode formed over the inter-layer insulator, a ferroelectric film and a upper electrode being stacked in order, the ferroelectric capacitor having a first side-wall, and a hydrogen barrier film covering the ferroelectric capacitor, wherein the first side-wall of the lower electrode includes a tilt having an angle to a bottom surface of the lower electrode and at least a portion of the tilt is more gradual than the tilt of the first side-wall of the upper electrode and the ferroelectric film, the first side-wall of the ferroelectric film continuing into the first side-wall of the lower electrode.

Further, another aspect of the invention, there is provided, a method for fabricating a semiconductor device having a ferroelectric memory cell, comprising, forming a transistor having a diffusion layer on a semiconductor substrate, forming an inter-layer insulator over the semiconductor substrate to cover the transistor, forming a contact plug connecting to the diffusion layer, forming a lower electrode film connecting to the contact plug, a ferroelectric film and an upper electrode film over the inter-layer insulator so as to be stacked in order, etching the upper electrode film, the ferroelectric film and the lower electrode film so as to form a ferroelectric capacitor having a first side-wall, and forming a hydrogen barrier film to cover the ferroelectric capacitor, wherein the first side-wall of the lower electrode includes a tilt having an angle to a bottom surface of the lower electrode and at least a portion of the tilt is more gradual than the tilt of the first side-wall of the upper electrode and the ferroelectric film, the first side-wall of the ferroelectric film continuing into the first side-wall of the lower electrode.

Further, another aspect of the invention, there is provided, a method for fabricating a semiconductor device having a ferroelectric memory cell, comprising, forming a transistor having a diffusion layer on a semiconductor substrate, forming an inter-layer insulator over the semiconductor substrate to cover the transistor, forming a contact plug connecting to the diffusion layer, forming a lower electrode film connecting to the contact plug, a ferroelectric film and an upper electrode film over the inter-layer insulator so as to be stacked in order, forming an etching mask on a formation region of the upper electrode, etching the upper electrode film or the upper electrode film and the ferroelectric film by using the etching mask, forming a side-wall mask, etching back the side-wall mask so as to form the side-wall mask at least on the side-wall of the upper electrode, etching the ferroelectric film and the lower electrode film by using the side-wall mask so as to form a ferroelectric capacitor having a first side-wall, forming a hydrogen barrier film to cover the ferroelectric capacitor, wherein the first side-wall of the lower electrode includes a tilt having an angle to a bottom surface of the lower electrode and at least a portion of the tilt is more gradual than the tilt of the first side-wall of the upper electrode and the ferroelectric film, the first side-wall of the ferroelectric film continuing into the first side-wall of the lower electrode.

### BRIEF DESCRIPTION OF THE DRAWINGS

FIG. 1 is a cross-sectional schematic view showing a structure of a semiconductor device having a ferroelectric capacitor according to a first embodiment of the present invention;

FIG. 2 is a cross-sectional schematic view showing the ferroelectric capacitor being a main structure component of the semiconductor device according to the first embodiment of the present invention;

FIGS. 3A-3C are cross-sectional schematic views showing the ferroelectric capacitor being the main structure component of the semiconductor device and a method for fabricating the semiconductor device in order according to the first embodiment of the present invention;

FIG. 4 is a cross-sectional schematic view showing a ferroelectric capacitor being a main structure component of a semiconductor device according to a first modification of the first embodiment of the present invention;

FIG. 5 is a cross-sectional schematic view showing a ferroelectric capacitor being a main structure component of a semiconductor device according to a second modification of the first embodiment of the present invention;

FIG. 6 is a cross-sectional schematic view showing a ferroelectric capacitor being a main structure component of a semiconductor device according to a third modification of the first embodiment of the present invention;

FIG. 7 is a cross-sectional schematic view showing a ferroelectric capacitor being a main structure component of a semiconductor device according to a fourth modification of the first embodiment of the present invention;

FIG. 8 is a cross-sectional schematic view showing a ferroelectric capacitor being a main structure component of a semiconductor device according to a fifth modification of the first embodiment of the present invention;

FIG. 9 is a cross-sectional schematic view showing a ferroelectric capacitor being a main structure component of a semiconductor device according to a sixth modification of the first embodiment of the present invention;

FIG. 10 is a cross-sectional schematic view showing a ferroelectric capacitor being a main structure component of a semiconductor device according to a second embodiment of the present invention;

FIGS. 11A-11C are cross-sectional schematic views showing the ferroelectric capacitor being the main structure component of the semiconductor device and a method for fabricating the semiconductor device in order according to the second embodiment of the present invention;

FIGS. 12A-12C are cross-sectional schematic views showing the ferroelectric capacitor being the main structure component of the semiconductor device and the method for fabricating the semiconductor device in order according to the second embodiment of the present invention;

FIG. 13 is a cross-sectional schematic view showing a ferroelectric capacitor being a main structure component of a semiconductor device according to a first modification of the second embodiment of the present invention;

FIG. 14 is a cross-sectional schematic view showing a ferroelectric capacitor being a main structure component of a semiconductor device according to a second modification of the second embodiment of the present invention;

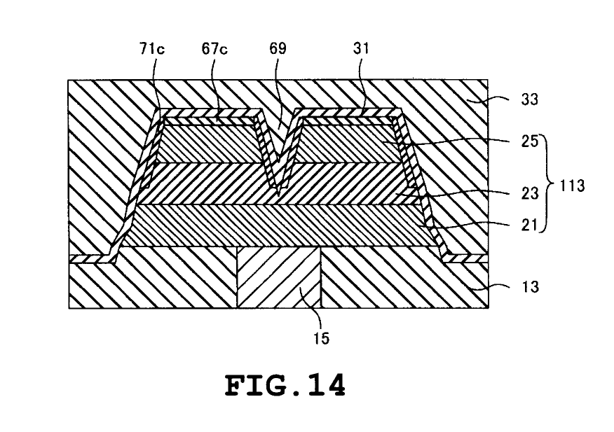

FIGS. 15A-15C are cross-sectional schematic views showing a ferroelectric capacitor being a main structure component of a semiconductor device according to a third modification of the second embodiment of the present invention;

FIG. 16 is a cross-sectional schematic view showing a ferroelectric capacitor being a main structure component of a semiconductor device according to a fourth modification of the second embodiment of the present invention;

FIG. 17 is a cross-sectional schematic view showing a ferroelectric capacitor being a main structure component of a semiconductor device according to a fifth modification of the second embodiment of the present invention;

FIG. 18 is a cross-sectional schematic view showing a ferroelectric capacitor being a main structure component of a semiconductor device according to a sixth modification of the second embodiment of the present invention;

FIG. 19 is a cross-sectional schematic view showing a ferroelectric capacitor being a main structure component of a semiconductor device according to a seventh modification of the second embodiment of the present invention;

FIGS. 20A-20C are cross-sectional schematic views showing a ferroelectric capacitor being a main structure component of a semiconductor device according to a eighth modification of the second embodiment of the present invention;

### DETAILED DESCRIPTION OF THE INVENTION

Various embodiments of the present invention will be described below in detail with reference to the accompanying drawings.

It is to be noted that the same or similar reference numerals are applied to the same or similar parts and elements throughout the drawings, and the description of the same or similar parts and elements will be omitted or simplified.

### First Embodiment

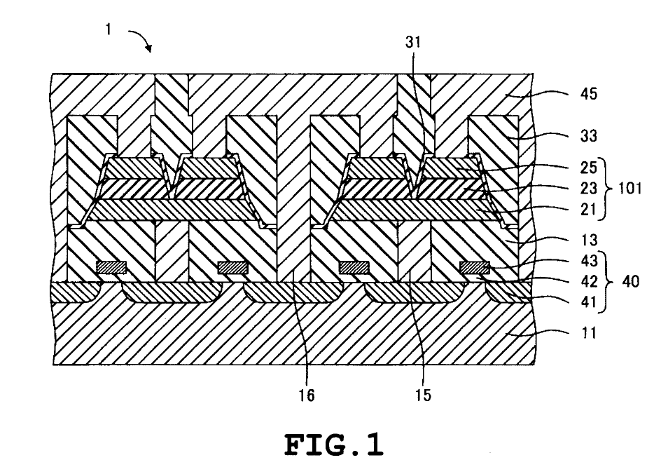

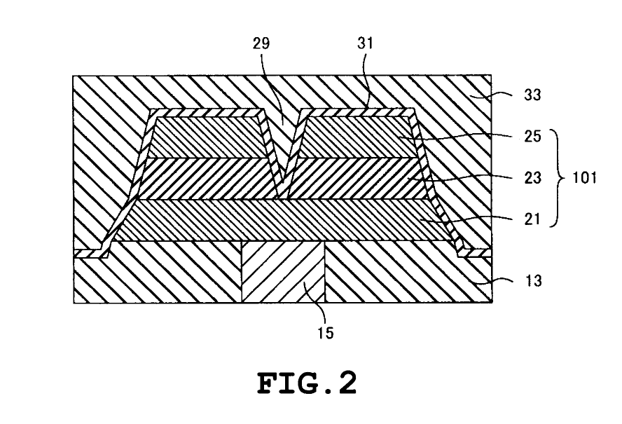

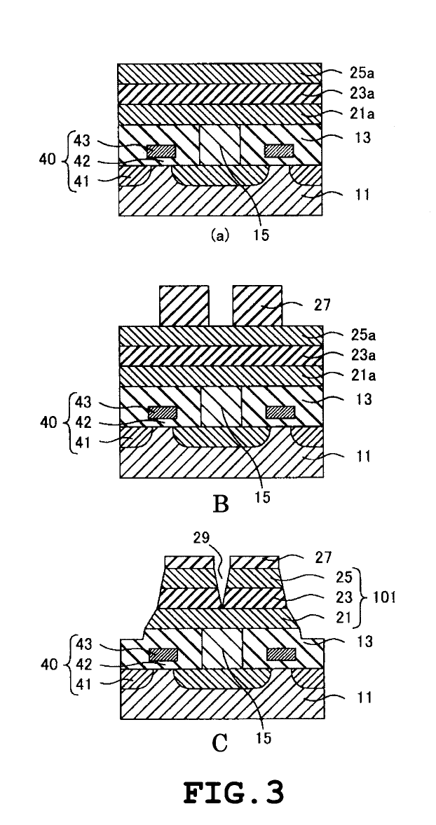

First, according to a first embodiment of the present invention, a semiconductor device and a method for fabricating the semiconductor device are explained with reference to FIGS. 1-3. FIG. 1 is a cross-sectional schematic view showing a structure of the semiconductor device having a ferroelectric capacitor according to the first embodiment of the present invention. FIG. 2 is a cross-sectional schematic view showing the ferroelectric capacitor being a main structure component of the semiconductor device. FIGS. 3A-3C are cross-sectional schematic views showing the ferroelectric capacitor being the main structure component of the semiconductor device and a method for fabricating the semiconductor device in order.

As shown in FIG. 1, a semiconductor device 1 includes a semiconductor substrate 11, a transistor 40 being formed on the semiconductor substrate 11, an inter-layer insulator 13 being formed over the transistor 40 to cover the transistor 40, a ferroelectric capacitor 101 being formed on the inter-layer insulator 13 via a contact plug 15, and a hydrogen barrier film 31 covering a surface including a side-wall of the ferroelectric capacitor 101.

The semiconductor substrate 11, for example, a p-type silicon substrate has an element region and the transistor 40 being formed in the element region. The transistor 40 is constituted of n-type diffusion layers 41 separately formed as a source or a drain on a surface of the element region in the semiconductor substrate 11 and a gate electrode 43 via a gate insulator 42 being formed on a portion of the semiconductor substrate 11 being interposed between a pair of the two diffusion layers 41.

The ferroelectric capacitor 101 has a structure being stacked a lower electrode 21, a ferroelectric film 23, and an upper electrode 25 in order from the transistor 40 at the lower side. The lower electrode 21 is connected to one of diffusion layers 41 in the transistor 40 via the contact plug 15 embedded in the inter-layer insulator 13. The contact plug 15 is composed of W, for example. The upper electrode 25 is connected to an interconnection layer 45 having a plug embedded in an inter-layer insulator 33 covering the interconnection layer 45 and is connected to the other diffusion layers 41 of the transistor 40 via a contact plug 16 embedded in the inter-layer insulator 13. The plug is composed of Al, for example, and the contact plug 16 is composed of W, for example. A cell is constituted of one ferroelectric capacitor 101 and one transistor having a switching function, the transistor being connected to the ferroelectric capacitor 101.

As shown in FIG. 2, a pair of the two ferroelectric capacitor 101 is constituted of the common lower electrode 21, two of the upper electrodes 25 isolated each other are disposed over the lower electrode 21. Two of the ferroelectric films 23 are formed between the lower electrode 21 and the upper electrode 25, each of the two ferroelectric films 23 being corresponding to each of the two upper electrodes 25, respectively. Each of outer side-walls of the pair of the two ferroelectric capacitors 101 is a slope with two steps. The lower portion of the slope, namely the side-wall of the lower electrode 21, is more gradual than the upper portion of the slope, namely the side-wall of the upper electrode 25 and the ferroelectric film 23. In other words, a tilt angle to the bottom surface of the lower electrode 21 is smaller than a tilt angle to the bottom surface of the upper electrode 25 and the ferroelectric film 23. Further, a surface of the inter-layer insulator 13 continuing to the side-wall of the lower electrode 21 is formed slightly at a lower portion from the bottom surface of the lower electrode 21.

Further, the pair of the two ferroelectric capacitors 101 is formed to be isolated by a V-shaped groove 29. Side-walls opposed to each other constituting the V-shaped groove 29 are side-walls of the upper electrode 25 and the ferroelectric film 23. A tilt angle of the side-wall forming the V-shaped groove 29 is approximately the same as the tilt angle of outer side-wall. Furthermore, a difference between the tilt angles is within a range of ±5 degrees. The bottom of the V-shaped groove 29 is coincident at an upper surface of the lower electrode.

The ferroelectric capacitor 101 is covered with a hydrogen barrier film 31 being composed of Al2O3, for example. As shown in FIG. 1, the hydrogen barrier film 31 has an opening used as a contact. An Al plug connecting to the upper electrode 25 is formed in the opening to be connected to the interconnection layer 45. The Al plug has an effect of suppressing hydrogen damage to the ferroelectric film 23 as comparing with W or the like.

Next, the method for fabricating the semiconductor device according to the first embodiment is explained.

As shown in FIG. 3A, the transistor 40 is formed on the semiconductor substrate 11 by a conventional method. The inter-layer insulator 13 is formed to cover the transistor 40. A contact hole is formed in the inter-layer insulator 13 and the contact plug 15 such as W or the like is embedded in the contact hole. After the processes mentioned above, a lower electrode film 21a, a ferroelectric film 23a and an upper electrode film 25a as materials for forming the ferroelectric capacitor 101 are deposited. The lower electrode film 21a is TiAlN/Ir including a barrier metal with a total film thickness of 150 nm, for example. Further, the lower electrode film 21a may be Ti/Ir or SrRuO₃ formed on Ir. The ferroelectric film 23a is Pb(ZrxTi₁₋ₓ)O₃ film (PZT film) with a film thickness of 100 nm, for example. The upper electrode film 25a is SrRuO₃/IrO₂ with a total film thickness of 80 nm, for example.

As shown in FIG. 3B, an etching mask 27 is formed for delineating the upper electrode film 25a by using a photo-lithography process. A mask interval for forming the pair of the two ferroelectric capacitors 101 is set up at a distance stopping an etching of the ferroelectric film 23a at a lower portion by micro-loading effect during dry etching in a following process.

Here, the mask 27 is composed of a hard mask with an Al₂O₃/SiO₂ stacked in layer. Further, the hard mask may be TiAlN/SiO₂, SiOx (for example, SiO₂), AlxOy (for example, Al₂O₃), SiAlxOy (for example, SiAlO), ZrOx (for example, ZrO₂), SixNy (for example, Si₃N₄), TiAlxNy (for example, TiAl_{0.5}N_{0.5}) or the like, or a composite of the materials mentioned above. Here, x and y in the chemical formula are showed, respectively, as a composition ratio of more than 1%. Further, in a case of high temperature RIE being more than approximately 200° C., a hard mask is necessary as the mask 27, however, in a case of low temperature RIE, the mask 27 is not restricted to the hard mask, but a photo-resist can be used.

As shown in FIG. 3C, the upper electrode film 25a and the ferroelectric film 23a are continuously delineated by dry etching (RIE) using the mask 27. For a tilt of etched surface is conducted to be gradual without stopping dry etching, an acceleration voltage of Ar in RIE is lowered, namely a bias power in RIE is weakened. The lower electrode film 21a is etched and successively the inter-layer insulator 13 is slightly over-etched, for example, with 20-50 nm depth. In the series of the etching processes, the etching of the lower electrode film 21a is normally performed at a portion with a wide interval in the mask 27 (a left side and a right side in FIG. 3C), on the other hand, the etching of the lower electrode film 21a is not effectively performed at a portion with a narrow interval in the mask 27 (a center area in FIG. 3C) by the micro-loading effect. Further, etching rate can be lowered by SrRuO₃ formed on the upper surface of the lower electrode film 21a.

As a result, the upper electrode film 25a, the ferroelectric film 23a, and the lower electrode film 21a etched by the processes become the upper electrode 25, the ferroelectric film 23, and the lower electrode 21 of the ferroelectric capacitor 101. The outer side-wall of the pair of the two ferroelectric capacitors 101 has the slope with the two steps. The lower portion, namely the tilt of the lower electrode 21, is more gradual than the upper portion, namely the tilt of the side-walls of the upper electrode 25 and ferroelectric film 23.

The upper electrode 25 and the ferroelectric film 23 in the pair of the two ferroelectric capacitors 101 are isolated by the V-shaped groove 29. The opposed side-walls forming the V-shaped groove 29 are constituted of the side-walls of the upper electrode 25 and the ferroelectric film 23 and the tilt of the opposed side-walls is nearly the same as the tilt of the upper portion in the outer side-walls of the pair of the two ferroelectric capacitors 101. A difference between the two tilts is less than ±5 degrees.

Next, the mask 27 is removed, as shown in FIG. 1 or FIG. 2, the hydrogen barrier film 31, for example, Al₂O₃ is formed to cover the ferroelectric capacitor 101 by sputtering technology. Especially, the mask 27 may be remained when the film is thin, for example, below 50 nm. In modification embodiments mentioned after, the mask may be remained as the same as the case mentioned above. A residual mask 27 being thinned by the etching leads to lower damages in the ferroelectric capacitor 101. A film thickness of the hydrogen barrier film 31, for example, is approximately 10 nm on the side-wall of the lower electrode 21 being most difficult for forming a film, is approximately 10 nm on the lower side-wall opposed groove 29 and is approximately 40 nm on the side-wall of the upper electrode 25 being most simply for forming a film, respectively.

Here, the hydrogen barrier film 31 is SiOx (for example, SiO₂), AlxOy (for example, Al₂O₃), SiAlxOy (for example, SiAlO), ZrOx (for example, ZrO₂), SixNy (for example, Si₃N₄), TiAlxNy (for example, TiAl_{0.5}N_{0.5}) or the like, or a composite of the materials mentioned above which has capability of preventing penetration of hydrogen into the hydrogen barrier film 31.

Furthermore, the inter-layer insulator 33 is deposited to cover the ferroelectric capacitor 101 and is planarized. Near the ferroelectric capacitor 101, the W plug connecting to the contact plug 15 and the Al plug connecting to the upper electrode 25 are formed. The interconnection layer 45 composed of Al connecting to the W plug, the Al plug or the like is formed. Moreover, the semiconductor device 1 is completed by using conventional fabrication processes.

As mentioned above, the outer side-wall of the pair of the two ferroelectric capacitors 101 is the slope with the two steps in the semiconductor device 1. The tilt of the side-wall of the lower electrode 21 in the lower portion is formed more gradual than the tilt of the side-wall of the upper portion in the upper electrode 25 and the ferroelectric film 23. On the other hand, the upper electrode 25 and the ferroelectric film 23 in the pair of the two ferroelectric capacitors 101 are isolated each other by the V-shaped groove 29 having nearly the same tilt within ±5 degrees as the tilt of the outer side-walls. Furthermore, the hydrogen barrier film 31 on the surface of the ferroelectric capacitor 101 has the film thickness of more than 5 nm, which means full hydrogen barrier capability, on the side-wall of the lower electrode 21 in the lower portion. Simultaneously, the hydrogen barrier film 31 has the film thickness of more than 5 nm on the lower portion of the side-wall in the V-shaped groove 29.

Furthermore, reasons why the hydrogen barrier film 31 is reliably formed are mentioned below. First, a film thickness is decreased with shaping the tilt of the adhered plane to the perpendicular plane of the material-input direction in sputtering. Furthermore, a film thickness is decreased at the tilt plane with leaving from the upper end portion. As a result, the tilt of the side-wall of the lower electrode 21 is made gradual and the V-shaped groove 29 is not necessarily deep as the constitution.

Consequently, the semiconductor device 1 becomes larger at the side direction due to the tilt of the side-wall lower electrode 21 in the ferroelectric capacitor 101 being gradual. As the film thickness of the hydrogen barrier film on the upper electrode is not extremely increased and the ferroelectric film 23 is covered with the hydrogen barrier film 31, the ferroelectric film 23 is reliably shielded from hydrogen.

Namely, the ferroelectric film 23a is reduced by a reduction gas such as hydrogen or the like included in the fabrication processes for the semiconductor device 1, as a result, spontaneous polarization amount is lowered and generation of degradation of characteristic of ferroelectric capacitor 101 is lowered. When the opening in the hydrogen barrier film on the upper electrode is formed to form a contact, as being extremely increased with the film thickness of the hydrogen barrier film on the upper electrode is suppressed, generation of failure is suppressed at the contact to be improved a yield of the semiconductor device 1.

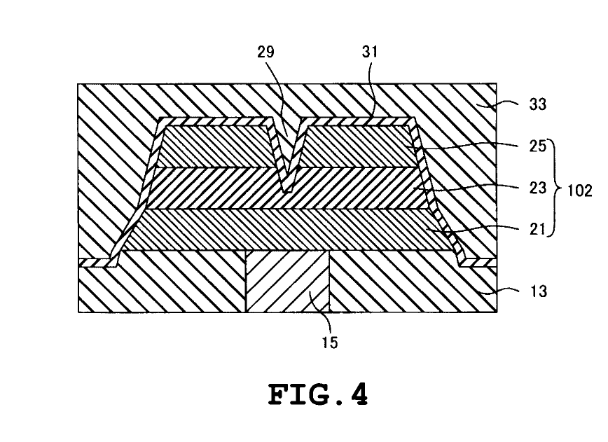

As a first modification of the first embodiment, as shown in FIG. 4, a ferroelectric capacitor 102 is formed. A different point as comparing with the first embodiment is that interval at an upper end of the opposed side-walls between the pair of the two ferroelectric capacitors 102 is narrowed in the ferroelectric capacitor 102, therefore, the bottom of the V-shaped groove 29 formed by the opposed side-walls is positioned in the ferroelectric film 23.

Consequently, an upper end at the opening of the V-shaped groove 29 is narrower and a depth of the V-shaped groove 29 is shallower. On the other hand, as an aspect ratio (the depth of the groove/the opening width of the groove) of the groove 29 is the same as the aspect ratio in the first embodiment, the hydrogen barrier film 31 formed on the side-wall of the groove 29 has a full thickness for blocking damages by hydrogen reduction. Therefore, the total hydrogen barrier film 31 has the same effect as the first embodiment. Furthermore, as comparing with the case of the first embodiment, the interval between the pair of the two ferroelectric capacitors 102 is narrowed, the size of the ferroelectric capacitors 102 can be small. Accordingly, miniaturization of a cell can be performed so as to lead to higher integration of the semiconductor device using the ferroelectric capacitor 102.

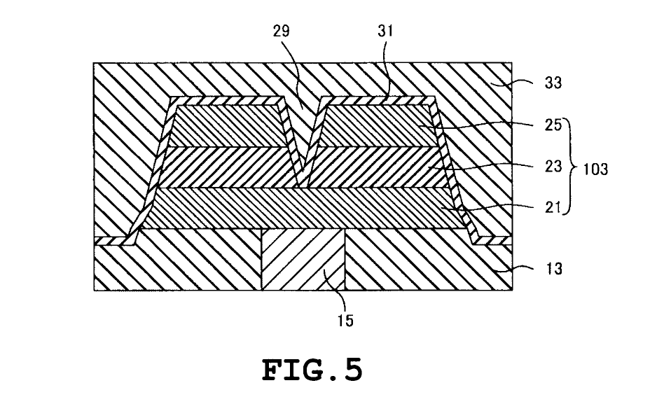

As a second modification of the first embodiment, as shown in FIG. 5, a ferroelectric capacitor 103 is formed. A different point as comparing with the first embodiment is that the tilt of a lower half portion in the lower electrode 21 is formed more gradual than the tilt of the upper electrode 25, the ferroelectric film 23 and an upper half portion in the lower electrode 21 in the outer side-wall of the pair of the two ferroelectric capacitors 103 so that the outer side-wall has the slope of two steps. Namely, a position changing the tilt is moved to lower side as comparing with the first embodiment.

Consequently, a portion with the side-wall tilt being gradual is lowered so that the hydrogen barrier film 31 is deposited by slower rate as comparing with the first embodiment. However, the hydrogen barrier film 31 formed on the side-wall of the groove 29 has a full thickness for blocking damages by generated hydrogen reduction. Therefore, the second modification has the same effect as the first embodiment.

Furthermore, as the portion with the side-wall tilt being more gradual is less in the lower electrode 21, the size of the pair of the two ferroelectric capacitors 102 can be small. Therefore, the area occupied by ferroelectric capacitors 104 can be small. Accordingly, miniaturization of the cell can be performed so as to lead to higher integration of the semiconductor device using the ferroelectric capacitor 103.

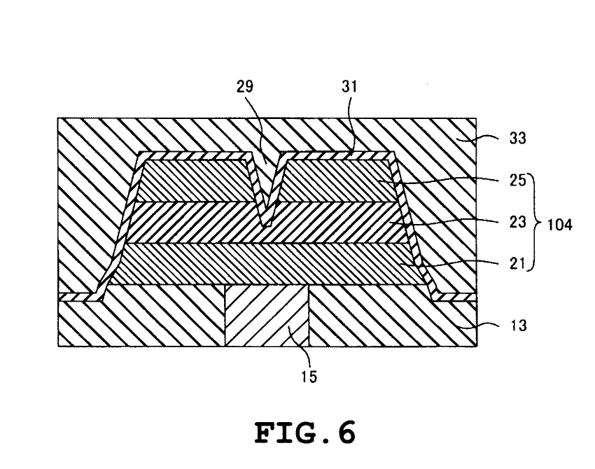

As a third modification of the first embodiment, as shown in FIG. 6, a ferroelectric capacitor 104 is formed. A different point as comparing with the first embodiment is that the upper end interval of opposed side-walls between the pair of the two ferroelectric capacitors 104 is narrower in the ferroelectric capacitor 104, therefore, the bottom of the V-shaped groove 29 formed by the opposed side-walls is positioned in the ferroelectric film 23. The tilt of the lower half portion in the lower electrode 21 is formed more gradual than the tilt of the upper electrode 25, the ferroelectric film 23 and the upper half portion in the lower electrode 21 in the outer side-walls of the pair of the two ferroelectric capacitors 103 so that the outer side-walls has the slope of two steps. Namely, the groove 29 is formed shallower and the position changing the tilt is moved to lower side as comparing with the first embodiment.

Consequently, the third modification of the first embodiment has the same effect as the second modification of the first embodiment. Furthermore, as the size of the pair of the two ferroelectric capacitors 104 can be small, the area occupied by ferroelectric capacitors 104 can be small. Accordingly, miniaturization of the cell can be performed so as to lead to higher integration of the semiconductor device using the ferroelectric capacitor 103.

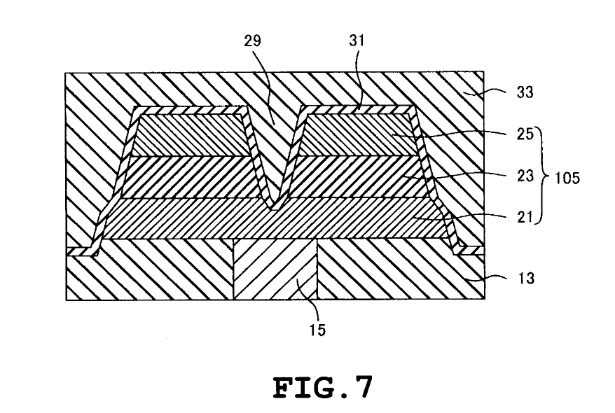

As a forth modification of the first embodiment, as shown in FIG. 7, a ferroelectric capacitor 105 is formed. A different point as comparing with the first embodiment is that the tilt of the lower half portion in the lower electrode 21 is formed more gradual than the tilt of the upper electrode 25, the ferroelectric film 23 and the upper half portion in the lower electrode 21 in the outer side-wall of the pair of the two ferroelectric capacitors 105 so that the outer side-walls has a slope of two tilts and three steps.

Further, the interval of the upper end of the opposed side-walls in the pair of the two ferroelectric capacitors 104 is widened in a range without widening the outer side-wall. The bottom of the V-shaped groove 29 formed by the opposed side-walls is positioned within the lower electrode 21. Furthermore, when a material film of the ferroelectric capacitor 105 is etched, a bias power is changed two times. For example, a prescribed bias power is used in the beginning, subsequently the bias power is weakened and further the bias power is reset at the beginning condition.

Consequently, the portion with a gradual tilt is only the upper half portion of the lower electrode 21 and the lower half portion of the lower electrode 21 has a shaper tilt. However, another portion with a gradual tilt is near an interface between the ferroelectric film 23 and the lower electrode 21 so as to retain the thickness of the hydrogen barrier film 31 at the necessary portion. As a result, an effect of the hydrogen barrier film 31 on protecting the ferroelectric film 23 is nearly the same as the first embodiment. Furthermore, the opening of the V-shaped groove 29 and the portion with the tilt being gradual is formed so that the aspect ratio becomes small and the hydrogen barrier film 31 is formed thicker than the thickness in the bottom of the groove 29 in the first embodiment. Namely, the same effect as the first embodiment is obtained and the effect of hydrogen barrier on the groove 29 is larger.

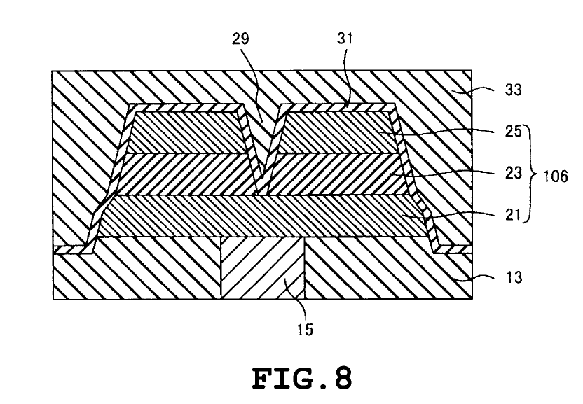

As a fifth modification of the first embodiment, as shown in FIG. 8, a ferroelectric capacitor 106 is formed. A different point as comparing with the fourth modification of the first embodiment is that the upper end interval of the opposed side-walls between the pair of the two ferroelectric capacitors 106 is formed to be narrower in the ferroelectric capacitor 106, on the other hand, is the same as the first embodiment interval. Therefore, the bottom of the V-shaped groove 29 formed by the opposed side-walls is positioned in the upper surface of the lower electrode 21.

Consequently, the fifth modification of the first embodiment has the same shape as the fourth modification of the first embodiment in the outer side-walls of the pair of the two ferroelectric capacitors 106 and in the V-shaped groove 29 of the opposed side-walls of the pair of the two ferroelectric capacitors 106. Therefore, the effect of the hydrogen barrier film 31 on protecting the ferroelectric film 23 is effectively the same as the first embodiment.

Furthermore, as the portion with the side-wall tilt being more gradual is less in the lower electrode 21, the size of the pair of the two ferroelectric capacitors 106 can be small. Further, the area occupied by ferroelectric capacitors 106 can be small. Accordingly, miniaturization of the cell can be performed so as to lead to higher integration of the semiconductor device using the ferroelectric capacitor 106.

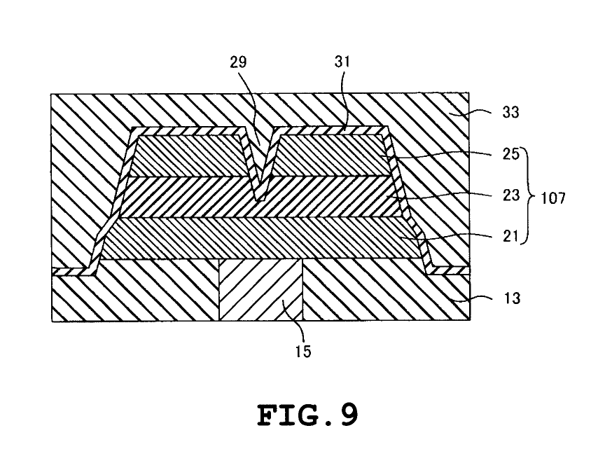

As a sixth modification of the first embodiment, as shown in FIG. 9, a ferroelectric capacitor 107 is formed. A different point as comparing with the fifth modification of the first embodiment is that the upper end interval of the opposed side-walls between the pair of the two ferroelectric capacitors 107 is formed to be narrower in the ferroelectric capacitor 107, on the other hand, is the same as the first modification of the first embodiment interval. Therefore, the bottom of the V-shaped groove 29 formed by the opposed side-walls is positioned in the ferroelectric film 23.

Consequently, the sixth modification of the first embodiment has the same shape as the fourth modification of the first embodiment and the fifth modification of the first embodiment in the outer side-walls of the pair of the two ferroelectric capacitors 107 and in the V-shaped groove 29 of the opposed side-walls of the pair of the two ferroelectric capacitors 106. Therefore, the effect of the hydrogen barrier film 31 on protecting the ferroelectric film 23 is effectively the same as the first modification of the first embodiment.

Furthermore, as the interval of the pair of the two ferroelectric capacitors 107 is narrowed, the size of the ferroelectric capacitor 107 can be small. Accordingly, miniaturization of the cell can be performed so as to lead to higher integration of the semiconductor device using the ferroelectric capacitor 107.

### Second Embodiment

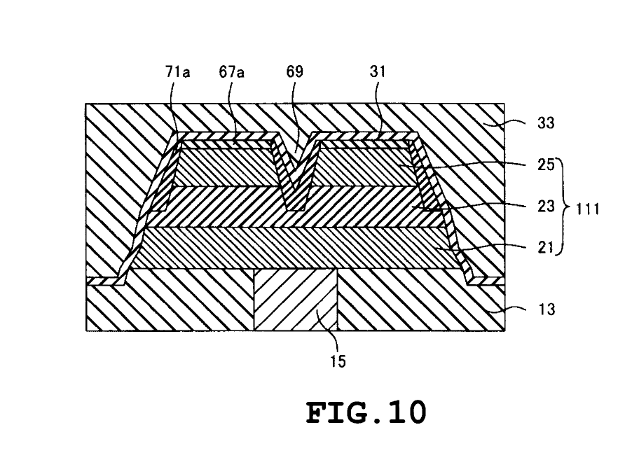

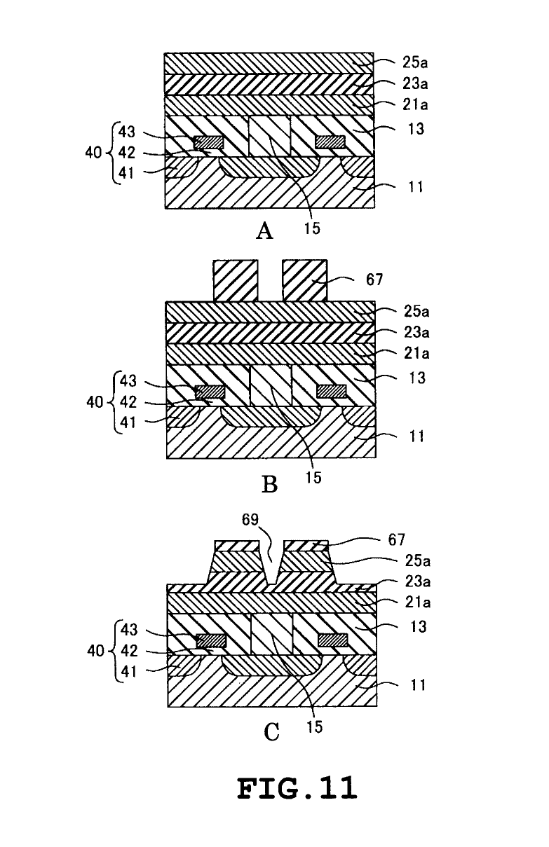

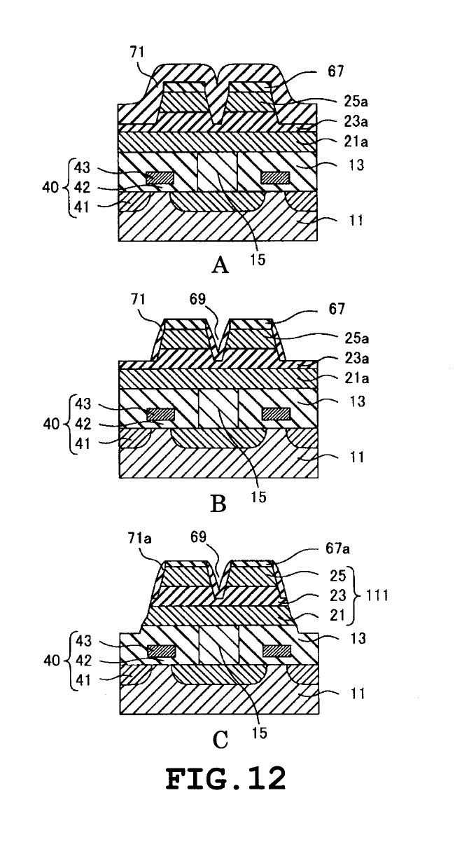

Next, according to a second embodiment of the present invention, a semiconductor device and a method for fabricating the semiconductor device are explained with reference to FIGS. 10-12. FIG. 10 is a cross-sectional schematic view showing a ferroelectric capacitor being a main structure component of the semiconductor device according to the second embodiment of the present invention. FIGS. 11A-11C are cross-sectional schematic views showing the ferroelectric capacitor being the main structure component of the semiconductor device and the method for fabricating the semiconductor device in order according to the second embodiment of the present invention. As following to FIGS. 11A-11C previously described, FIGS. 12A-12C are cross-sectional schematic views showing the ferroelectric capacitor being the main structure component of the semiconductor device and the method for fabricating the semiconductor device in order according to the second embodiment of the present invention.

Different points of the ferroelectric capacitor in the second embodiment as comparing with the ferroelectric capacitor in the first embodiment are mentioned below. A structure of the ferroelectric capacitor in the second embodiment has a mask film or a side-wall film on an upper surface and a side surface of an upper electrode, and a side surface of the ferroelectric film capacitor. Further, it is to be noted that the same or similar reference numerals as the first embodiment are applied to the same or similar parts and elements throughout the drawings, and the description of the same or similar parts and elements as the first embodiment will be omitted or simplified.

As shown in FIG. 10, a ferroelectric capacitor 111 includes a mask film 67a on the surface of the upper electrode 25 and a side wall film 71a on the side surface of the upper electrode 25 and an upper side surface of the ferroelectric film 23. As comparing with a tilt of an outer side-wall of the ferroelectric film 23 being in series with the side wall film 71a and a tilt of the outer side-wall of the upper portion in the lower electrode 21, a tilt of the outer side-wall of the lower portion in the lower electrode 21 is gradual. The upper electrode 25 and the upper portion of the ferroelectric film 23 is almost formed of the V-shape in the pair of the two ferroelectric capacitors 111 and includes the side wall film 71a on the V-shape as the same as the outer side surface. The capacitor 111 is covered with hydrogen barrier film 31 composed of an oxide film, for example, Al₂O₃, on the side-wall film 71a except the lower portion of the lower electrode 21.

Further, when the Al plug connecting to the upper electrode 25 is formed (illustrated in FIG. 1 as reference) the hydrogen barrier film 31 and the mask film 67a has an opening and the ferroelectric capacitor 111 is connected to the interconnection layer 45 via the opening. Another structure is the same as the ferroelectric capacitor 101 in the first embodiment. Accordingly, the semiconductor device 1 (not illustrated) having the ferroelectric capacitor 111 is constituted as the same as the semiconductor device of the first embodiment.

Next, the method for fabricating the semiconductor device according to the second embodiment is explained. As shown in FIG. 11A and FIG. 11B, fabricating the transistor 40, depositing the lower electrode film 21a, the ferroelectric film 23a, the upper electrode film 25a and the like as material films of the ferroelectric capacitor 111 is almost the same as the processing steps in FIGS. 3A and 3B according to the first embodiment. The ferroelectric capacitor 111 is formed by using a side wall mask mentioned below. An interval for forming a position of the etching mask 67, namely a pair of the upper electrodes 25 is a different process, however, another processes are the same as the processes of the mask 27.

As shown in FIG. 11C, the upper electrode film 25a and a part of the ferroelectric film 23a, for example, are etched into a center portion of the film thickness using the mask 67 by dry etching (RIE). A portion with a narrow interval between the masks 67 (a center portion in FIG. 11C) is almost formed as the V-shaped groove 69. Here, the mask 67 is remained.

As shown in FIG. 12A, the side-wall film 71 of the oxide film as the side wall mask is deposited on the upper electrode film 25a and the ferroelectric film 23a. The side-wall film 71, Al₂O₃ of the film thickness having approximately 40 nm of a highly selective mask material film is formed by sputtering technique, ALD (Atomic Layer Deposition) technique or both of the two processes. The SiO2 film of the film thickness having approximately 50 nm is formed on the side wall film 71. Further, the highly selective mask material as the side wall film 71 can be selected from SiOx film (for example, SiO₂ film), AlxOy film (for example, Al₂O₃ film), SiAlxOy film (for example, SiAlO film), ZrOx film (for example, ZrO₂ film), SixNy film (for example, Si₃N₄ film), or a composite of the materials mentioned above. Here, x and y in the chemical formula is showed, respectively, as a composition ratio of more than 1%.

As shown in FIG. 12B, the side-wall film 71 is formed by etch-back to residue the side-wall of the upper electrode film 25a and the side-wall of the upper half portion in the ferroelectric film 23a. The mask 67 is partially remained at the upper surface of the upper electrode film 25a.

As shown in FIG. 12C, the side-wall of a partial of the ferroelectric film 23a, the lower electrode film 21a and the like is etched by RIE using the mask 67 and the side-wall film 71 as the mask. The lower portion of the ferroelectric film 23a and the upper half portion of the lower electrode film 21a are dry-etched. Successively, for a tilt of etched surface being conducted to be gradual without stopping dry etching, an acceleration voltage of Ar in RIE is lowered, namely a bias power in RIE is weakened. The lower electrode film 21a is etched and successively the inter-layer insulator 13 is slightly over-etched, for example, with below 20 nm depth.

As a result, the upper electrode film 25a, the ferroelectric film 23a, and the lower electrode film 21a etched by the processes mentioned above become the upper electrode 25, the ferroelectric film 23, and the lower electrode 21 of the ferroelectric capacitor 111. The outer side-walls of the pair of the two ferroelectric capacitors 101 with the side-wall film 71 at the side of the upper electrode 25 have the slope with the two steps. The lower portion, namely the tilt of the lower half portion of the lower electrode 21, is more gradual than the upper portion, namely the tilt of the side-walls of the upper electrode 25, the ferroelectric film 23 and the upper half portion of the lower electrode 21. The mask 67 and the side-wall film 71 are thinned, respectively, so as to remain as the mask film 67a and the side wall film 71a.

Next, after the mask film 67a and the side wall film 71a is remained, as shown in FIG. 10, Al₂O₃ being the hydrogen barrier film 31 is formed to cover the ferroelectric capacitor 111 by sputtering technique, for example, as same as the first embodiment. The film thickness of the hydrogen barrier film 31, for example, is approximately 10 nm on the side-wall of the lower half portion of the lower electrode 21 being most difficult for forming a film, is approximately above 10 nm on the lower side-wall opposed groove 69 and is approximately 40 nm on the side-wall of the upper electrode 25 being most simply for forming a film, respectively.

Moreover, the semiconductor device 1 is completed by using conventional fabrication processes as same as the first embodiment.

As mentioned above, the outer side-wall of the pair of the two ferroelectric capacitors 111 has the slope with the two steps in the semiconductor device 1. The tilt of the side-wall of the lower half portion of the lower electrode 21 in the lower portion is formed more gradual than the tilt of the side-wall of the upper portion in upper electrode 25 and the ferroelectric film 23. On the other hand, the upper electrode 25 and the upper half portion of the ferroelectric film 23 in the pair of the two ferroelectric capacitors 111 is isolated by the V-shaped groove 69 having nearly the same tilt within ±5 degrees as the tilt of the outer side-walls. Furthermore, the hydrogen barrier film 31 on the surface of ferroelectric capacitor 111 has the film thickness of more than 5 nm, which means full hydrogen barrier capability, on the side-wall of the lower electrode 21 in the lower portion. Simultaneously, the hydrogen barrier film 31 has the film thickness of more than nearly 5 nm on the lower portion of the side-wall in the V-shaped groove 69.

Consequently, the semiconductor device according to the second embodiment has the same effect as the semiconductor device 1 according to the first embodiment.

Furthermore, the side-walls of the pair of the two ferroelectric capacitors 111 are formed of the V-shaped groove 29 having the bottom nearly at the center in the film thickness of the ferroelectric 23. The side-wall and the bottom of the two capacitors 111 have the side-wall film 71a. As a result, the tilt of the hydrogen barrier 31 becomes gradual and the thickness of the hydrogen barrier 31 is a full thickness to block damages by reduction of hydrogen.

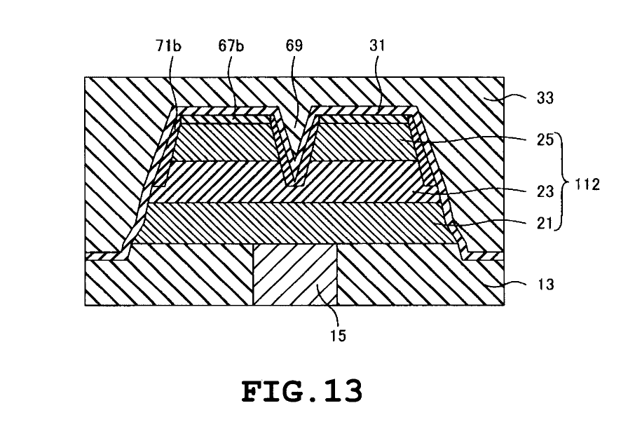

As a first modification of the second embodiment, as shown in FIG. 13, a ferroelectric capacitor 112 is formed. A different point as comparing with the second embodiment is that film thicknesses of a mask film 67c and a side-wall film 71c are thinner than those of the mask film 67a and the side-wall film 71a in the second embodiment. The side-walls of the pair of the two ferroelectric capacitors 112 are formed as the V-shaped groove 69. As the film thickness of side-wall film 71c is thinner, the hydrogen barrier film 31 is closely formed with the ferroelectric film 23. The outer side-walls of the pair of the two ferroelectric capacitors 114a are the same as those of the second embodiment.

Consequently, the film thickness of the hydrogen barrier film 31 on the ferroelectric capacitor 112 is the same at the outer side-wall and is thinner at the side-wall of the groove 69, as comparing with the film thickness of the hydrogen barrier film 31 in the second embodiment. However, both of the film thicknesses are fully formed for blocking damages by hydrogen reduction. Further, as the film thickness of the side-wall film 71b is thinner than that in the second embodiment, the size of the ferroelectric capacitor 112 can be small.

Furthermore, the contact opening on the upper electrode of the capacitor is easily performed to improve a yield of the semiconductor devices. Accordingly, miniaturization of the cell can be performed so as to lead to higher integration of the semiconductor device using the ferroelectric capacitor 112.

As a second modification of the second embodiment, as shown in FIG. 13, a ferroelectric capacitor 113 is formed. A different point as comparing with the first modification of the second embodiment is that film thicknesses of a mask film 67c and a side-wall film 71c are thinner than those of the mask film 67a and the side-wall film 71a in the first modification of the second embodiment. The side-walls of the pair of the two ferroelectric capacitors 112 are formed as the V-shaped groove 69 further having a second groove formed by the etching of the side-wall film 71c being at the bottom. As the film thickness of the side-wall film 71c is thinner, the hydrogen barrier film 31 is formed into the ferroelectric film 23. The outer sidewalls of the pair of the two ferroelectric capacitors 114a are the same as that of the second embodiment.

Consequently, the film thickness of the hydrogen barrier film 31 on the ferroelectric capacitor 113 is the same at the outer side-wall and is thinner at the side-wall of the groove 69, as comparing with the film thickness of the hydrogen barrier film 31 in the first modification of the second embodiment. However, both of the film thicknesses are fully formed for blocking damages by hydrogen reduction. Further, as the film thickness of side-wall film 71c is thinner than that in the first modification of the second embodiment, the size of the ferroelectric capacitor 113 can be small, therefore, miniaturization of the cell can be performed so as to lead to higher integration of the semiconductor device using the ferroelectric capacitor 113. Furthermore, the contact opening on the upper electrode of the capacitor is easily performed to improve a yield of the semiconductor devices. Accordingly, miniaturization of the cell can be performed so as to lead to higher integration of the semiconductor device using the ferroelectric capacitor 113.

As a third modification of the second embodiment, as shown in FIG. 13A-13C, a ferroelectric capacitor 114 is formed. A different point as comparing with the second modification of the second embodiment is that film thicknesses of a mask film 67d and a side wall film 71d are thinner than those of the mask film 67c and the side-wall film 71c in the second modification of the second embodiment. For example, the upper SiO2 film is removed. The side-walls of the pair of the two ferroelectric capacitors 114a are formed as the V-shaped groove 69 further having a deeper second groove as the two step formed by the etching of the side-wall film 71d being at the bottom. As the film thickness of side wall film 71d is thinner, the hydrogen barrier film 31 is formed into the ferroelectric film 23. The outer sidewalls of the pair of the two ferroelectric capacitors 114a are the same as that of the second embodiment.

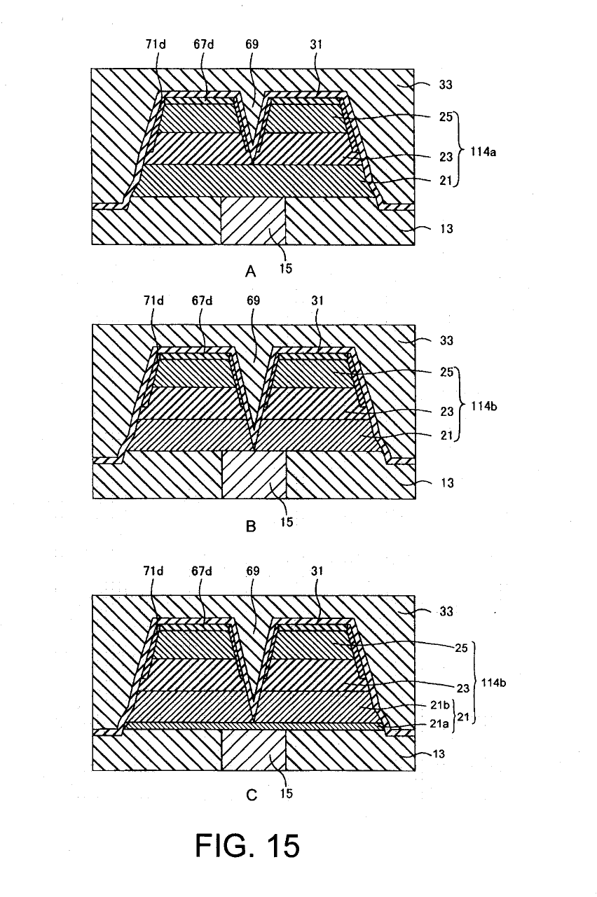

Further, FIG. 15B shows a preserve interval between the pair of the two ferroelectric capacitors 114b is widely formed as comparing with FIG. 15A. The groove 69 is a deeper V-type shape and a leading edge of the groove 69 extends to contact plug 15. Here, FIG. 15B shows a case being used Ti/Ir as the lower electrode 21. On the other hand, FIG. 15c shows a case being used TiAlN/Ir as the lower electrode 21. As the Ir film 21b is processed as the lower electrode 21, etching of the TiAlN film 21a is almost stopped so that the lower portion of the plug is not over-etched. The outer side-walls of the pair of the two ferroelectric capacitors 114b are the same as the second embodiment. Moreover, a medium shape of the ferroelectric capacitors 114a and 114b as shown in FIG. 15A and FIG. 15B can be existed.

Consequently, the film thickness of the hydrogen barrier film 31 on the ferroelectric capacitors 114a and 114b, are the same at the outer side-wall and is thinner at the side-wall of the groove 69, as comparing with the film thickness of the hydrogen barrier film 31 in the second modification of the second embodiment. However, both of the film thicknesses are fully formed for blocking damages by hydrogen reduction. Further, as the film thickness of a side-wall film 71d is thinner than that in the second modification of the first modification of the second embodiment, the size of the ferroelectric capacitors 114a and 114b can be small or the same as the case of the second modification of the second embodiment. Furthermore, the contact opening on the upper electrode of the capacitor is easily performed to improve a yield of the semiconductor devices. Accordingly, miniaturization of the cell can be performed so as to lead to higher integration of the semiconductor device using the ferroelectric capacitors 114a and 114b.

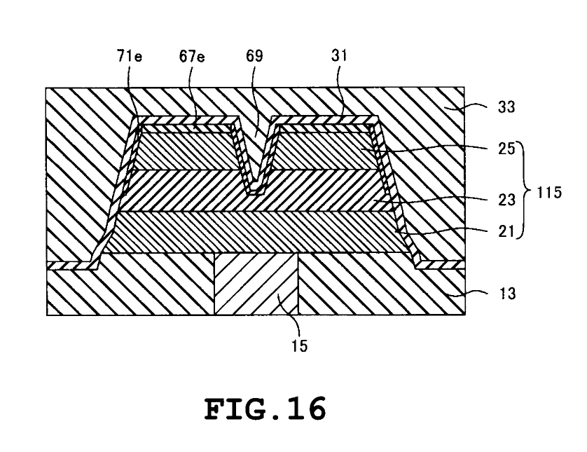

As a fourth modification of the second embodiment, as shown in FIG. 16, a ferroelectric capacitor 115 is formed. A different point as comparing with the third modification of the second embodiment is that the etching mask being shown as the mask 67 in FIG. 11 for a reference is configured at closely so that the pair of the two upper electrodes 25 is configured at more closely each other. The film thickness of a mask film 67e and a side-wall film 71e are formed thinner than those of the mask film 67d and the side wall film 71d in the third modification of the second embodiment. For example, the SiO2 film of the upper portion is removed. In another portion, the ferroelectric capacitor 115 is formed as the same as in the third modification of the second embodiment.

The side-walls of the pair of the two ferroelectric capacitors 115 are formed as the V-shaped groove 69. As the size of the upper end portion is small so that film thickness of the side-wall film 71e is thinner, the hydrogen barrier film 31 is formed at the bottom of the groove 69 with residual side-wall film 71e and the side-wall. The outer side-walls of the pair of the two ferroelectric capacitors 115 are the same as the second embodiment.

Consequently, the film thickness of the hydrogen barrier film 31 on the ferroelectric capacitor 115 is the same at the outer side-wall and is thinner at the side-wall of the groove 69, as comparing with the film thickness of the hydrogen barrier film 31 in the third modification of the second embodiment. However, both of the film thicknesses are fully formed for blocking damages by hydrogen reduction. Further, as the film thickness of side-wall film 71e is thinner than that in the third modification of the second embodiment by the pair of the two ferroelectric capacitors 111 being at closely to each other. The size of the ferroelectric capacitor 112 can be small, miniaturization of a cell can be performed. Furthermore, the contact opening on the upper electrode of the capacitor is easily performed to improve a yield of the semiconductor devices. Accordingly, higher integration of the semiconductor device using the ferroelectric capacitor 115 is performed.

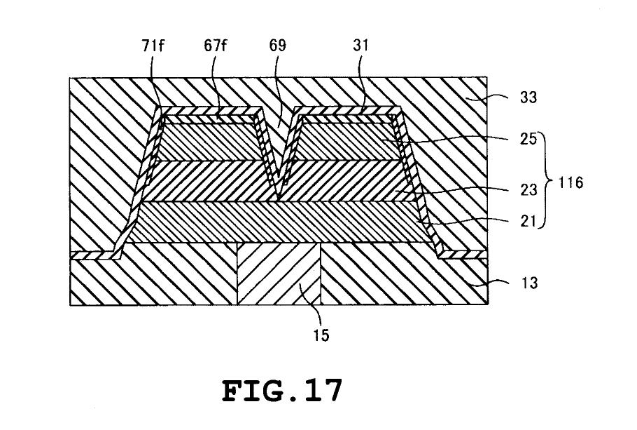

As a fifth modification of the second embodiment, as shown in FIG. 17, a ferroelectric capacitor 116 is formed. A different point as comparing with the fourth modification of the second embodiment is that the film thicknesses of a mask film 67f and a side wall film 71f are thinner than those of the mask film 67e and the side wall film 71e in the fourth modification of the second embodiment. For example, Al₂O₃ at the lower portion is removed. The side-walls of the pair of the two ferroelectric capacitors 116 are formed as the V-shaped groove 69 further having a second groove as the two steps formed by the etching of the side wall film 71f being at the bottom. As the film thickness of the side wall film 71f is thinner, the hydrogen barrier film 31 is formed into the ferroelectric film 23. The outer sidewalls of the pair of the two ferroelectric capacitors 116 are the same as that of the second embodiment.

Consequently, the film thickness of the hydrogen barrier film 31 on the ferroelectric capacitor 116 is the same at the outer side-wall and is thinner at the side-wall of the groove 69, as comparing with the film thickness of the hydrogen barrier film 31 in the fourth modification of the second embodiment. However, both of the film thicknesses are fully formed for blocking damages by hydrogen reduction. Further, as the film thickness of the side wall film 71f is thinner than that in the fourth modification of the second embodiment by the pair of the two ferroelectric capacitors 115 being at closely to each other, the size of the ferroelectric capacitor 115 can be small so that miniaturization of a cell can be performed. Furthermore, the contact opening on the upper electrode of the capacitor is easily performed to improve a yield of the semiconductor devices. Accordingly, higher integration of the semiconductor device using the ferroelectric capacitor 115 is performed.

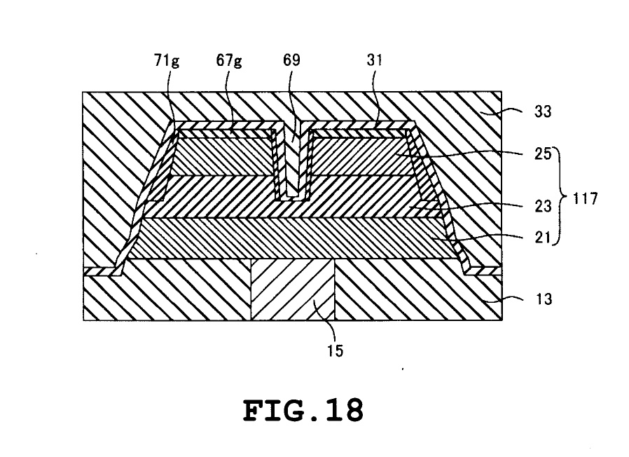

As a sixth modification of the second embodiment, as shown in FIG. 18, a ferroelectric capacitor 117 is formed. A different point as comparing with the second modification of the second embodiment is that the side-walls of the grooves 69 separating the pair of the two ferroelectric capacitors 117 have a shaper angle than the angle of the outer side-walls. A side-wall film 71g is formed on the side-wall of the groove 69 and the hydrogen barrier film 31 is formed on the side-wall film 71g. The outer side-walls of the pair of the two ferroelectric capacitors 114a are the same as those of the second embodiment. The side-wall film 71g on the side-wall of the groove 69 is described as a concave-type, however, a V-shaped type or a U-shaped type can also be existed as a modification.

Consequently, as the bottom groove 69 is configured nearly at the center of the ferroelectric film 23, the aspect ratio of the groove 69 is the same as the first embodiment and smaller than that of the second embodiment so that the film thickness of the hydrogen barrier film 31 at the bottom of the groove 69 is thinner. However, the film thickness is fully formed for blocking damages by hydrogen reduction. The hydrogen barrier film 31 of the outer sidewalls in the pair of the two ferroelectric capacitors 117 has the same thickness as that of the hydrogen barrier film 31 in the second embodiment. The film thickness is fully formed for blocking damages by hydrogen reduction. Further, the size of the ferroelectric capacitor 117 is almost the same as the ferroelectric capacitor 111 in the second embodiment.

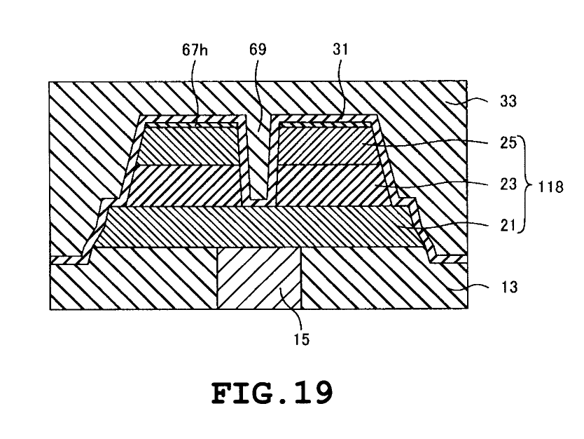

As a seventh modification of the second embodiment, as shown in FIG. 19, a ferroelectric capacitor 119 is formed. A different point as comparing with the sixth modification of the second embodiment is that the bottom of the groove 69 is the upper surface of the lower electrode 21 and the side wall film extended to the upper surface of the lower electrode 21 is removed. A thin mask film 67h on the upper electrode 25 becomes thinner to be remained. The side-walls of the pair of the two ferroelectric capacitors 118 are extended to the upper surface of the lower electrode 21 to form the deeper groove 69. The opening size becomes larger due to the opening without the side wall film. The outer side-walls of the pair of the two ferroelectric capacitors 118 are changed accompanying with removing the side wall film. The tilt of the upper electrode 25 and the ferroelectric film 23 becomes non-continuous by an appearance with the upper surface of the lower electrode 21. Subsequently, the tilt of the upper electrode 25 and the ferroelectric film 23 becomes continuous at the upper surface of the lower electrode 21 and has gradual tilt of the lower half portion of the lower electrode 21. Further, SrRuO3 on the lower half portion of the lower electrode 21 lead to easily forming of the bottom of the groove 69.

Consequently, the opening size of the groove 69 becomes larger due to the opening without the side wall film. As comparing with the sixth modification of the second embodiment, the deeper groove 69 can be formed with constant aspect ratio. Accordingly, the hydrogen barrier film 31 is formed thinner. However, the film thicknesses are fully formed for blocking damages by hydrogen reduction. As the upper surface of the lower electrode 21 with non-tilt between the ferroelectric film 23 and the lower electrode 21 lead to a full thickness of the hydrogen barrier film 31 on the lower electrode 21. The effect of the hydrogen barrier film 31 on protecting the ferroelectric film 23 is substantially exceeded the sixth modification of the second embodiment.

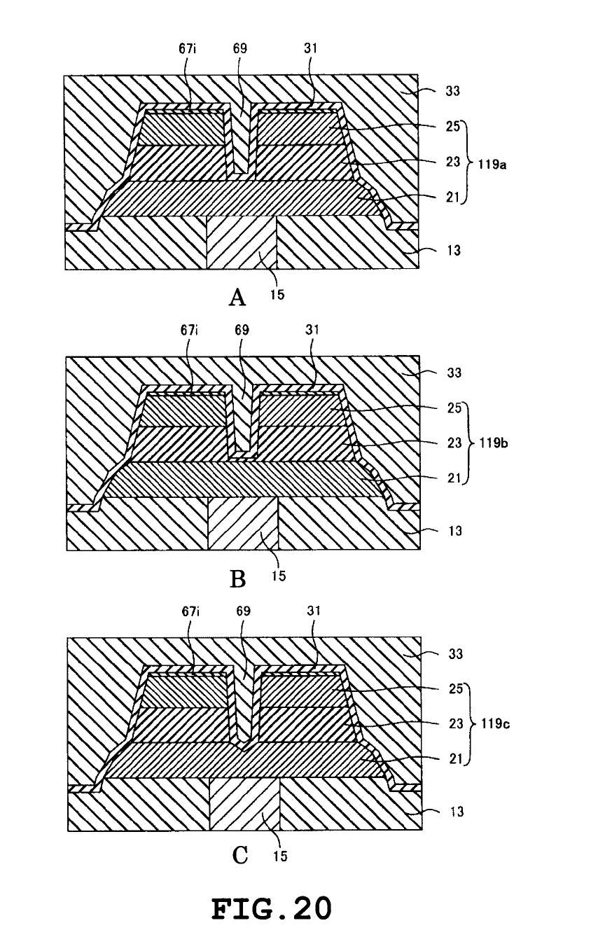

As a eighth modification of the second embodiment, as shown in FIG. 20A-20C, a ferroelectric capacitor 119a is formed. A different point as comparing with the seventh modification of the second embodiment is that the tilt of the side-wall of the upper half portion in the lower electrode 21 is formed more gradual than the tilt of the side-wall of the upper electrode 25 and the ferroelectric film 23. The tilt of the outer side-wall of the ferroelectric capacitor 119 is nearly the same as the tilt in the fourth modification of the first embodiment as shown in FIG. 7.

Further, as shown in FIG. 20B, the groove 69 is shallow than the case as shown in FIG. 20A, namely a ferroelectric capacitor 119b having the bottom of the groove 69 being in the ferroelectric film 23 is formed. On the other hand, as shown in FIG. 20C, a ferroelectric capacitor 119c, not a plane as shown in FIG. 20A, having the bottom of the groove 69 being formed in the lower electrode 21 and into the gradual V-shaped tilt is formed. Moreover, a medium shape the ferroelectric capacitors 114a and 114b as shown in FIGS. 20A, 20B and 20C can be existed.

Consequently, the opening of the groove 69 in the ferroelectric capacitor 119a has the same effect as the seventh modification of the second embodiment. The outer side-walls of the ferroelectric capacitor 119a have the same effect as the fourth modification of the first embodiment. The hydrogen barrier film 31 on the bottom of the ferroelectric capacitors 119b and 119c have full film thickness for blocking damages by hydrogen reduction as the same as the bottom of the groove 69 as shown in FIG. 20A.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

For example, various modifications will become possible for those skilled in the art after receiving the teachings of the present disclosure without departing from the scope thereof.

For example, forming the contact plug in the common lower electrode is shown in the embodiments. However, it can be probable to form each contact plug being corresponding to each ferroelectric capacitor.

Furthermore, for example, a ferroelectric capacitor is shown to be used as a chain-type FeRAM in the embodiments. A structure of the ferroelectric capacitor having an outer side surface in the embodiment can be applied to another-type FeRAM, for the example, a FeRAM having a ferroelectric capacitor and a transistor connected in series each other or the like.

Furthermore, the examples of a PZT film as a ferroelectric film is shown in the embodiments, however, a layered-oxide ferroelectric film having another perovskite-type crystal structure, for example, PZLT ((Pb, La)(Zr, Ti) O₃), SBT (SrBi₂Ta₂O₉) or the like can be used.

What is claimed is:

1. A semiconductor device having a ferroelectric memory cell, comprising:
a semiconductor substrate;
a transistor being formed on the semiconductor substrate;
an inter-layer insulator being formed over the transistor to cover the transistor;
a ferroelectric capacitor including a lower electrode formed over the inter-layer insulator, a ferroelectric film and a upper electrode being stacked in order, the ferroelectric capacitor having a first side-wall; and
a hydrogen barrier film covering the ferroelectric capacitor;
wherein the first side-wall of the lower electrode includes a tilt having an angle to a bottom surface of the lower electrode and at least a portion of the tilt is more gradual than the tilt of the first side-wall of the upper electrode and the ferroelectric film, the first side-wall of the ferroelectric film continuing into the first side-wall of the lower electrode.

2. The semiconductor device having the ferroelectric memory cell according to claim 1, further comprising:
a first diffusion region and a second diffusion region being included in the transistor, the first diffusion region and the second diffusion region being formed in the semiconductor substrate, the first diffusion region and the second diffusion region being connected to the lower electrode and the upper electrode via contact plugs, respectively.

3. The semiconductor device having the ferroelectric memory cell according to claim 1, further comprising:
an oxide film being included in the hydrogen barrier film, the oxide film covering the surface including the first side-wall of the ferroelectric capacitor.

4. The semiconductor device having the ferroelectric memory cell according to claim 1,
wherein the first side-wall of the lower electrode includes at least more than two kinds of the tilts, each of the tilts having a different angle to the bottom surface of the lower electrode, respectively, the most gradual tilt of the first side-wall of the lower electrode is more gradual than the tilt of the first side-wall of the lower electrode continuing to the first side-wall of the ferroelectric film.

5. The semiconductor device having the ferroelectric memory cell according to claim 1,
wherein a pair of the two ferroelectric capacitors is formed, each of the two ferroelectric capacitors is in parallel each other to a gate width direction, each outer side-wall of the two ferroelectric capacitors is the first side-wall, each opposed side-wall of the two ferroelectric capacitors is a second side-wall, each second side-wall of the upper electrode and the ferroelectric film has a tilt and is separated by a groove, respectively.

6. The semiconductor device having the ferroelectric memory cell according to claim 5,
wherein the tilt of the second side-wall is shaper than the tilt of the first side-wall.

7. The semiconductor device having the ferroelectric memory cell according to claim 5,
wherein an upper portion of the second side-wall of the ferroelectric film has the tilt and a lower portion of the second side-wall of the ferroelectric film is continued each other.

8. The semiconductor device having the ferroelectric memory cell according to claim 5,
wherein at least a portion of the second side-wall of the lower electrode has a tilt, and the portion of the second side-wall of the lower electrode as well as the second side-wall of the upper electrode and the ferroelectric film are separated with the groove.

9. The semiconductor device having the ferroelectric memory cell according to claim 3, wherein
the oxide film covers only the surface of the ferroelectric capacitor.

10. The semiconductor device having the ferroelectric memory cell according to claim 3,
wherein each of the two ferroelectric capacitors paired with each other is in parallel to a gate width of the transistor, each outer side-wall of the two ferroelectric capacitor is the first side-wall, each opposed side-wall of the two ferroelectric capacitor is the second side-wall, the second side-wall of the upper electrode and the ferroelectric film have the tilt and are separated by the groove.

11. The semiconductor device having the ferroelectric memory cell according to claim 10,
wherein the tilt of the second side-wall is sharper than the tilt of the first side-wall.

12. The semiconductor device having the ferroelectric memory cell according to claim 10,
wherein an upper portion of the second side-wall of each ferroelectric film has the tilt and is separated by the groove, and a lower portion of the second side-wall of each ferroelectric film is continued each other.

13. The semiconductor device having the ferroelectric memory cell according to claim 10,
wherein at least a portion of the second side-wall of each lower electrode has the tilt and the portion of the second side-wall of each lower electrode as well as the second side-wall of each upper electrode and each ferroelectric film is separated by the groove.

14. A method for fabricating a semiconductor device having a ferroelectric memory cell, comprising:
forming a transistor having a diffusion layer on a semiconductor substrate;
forming an inter-layer insulator over the semiconductor substrate to cover the transistor;
forming a contact plug connecting to the diffusion layer;
forming a lower electrode film connecting to the contact plug, a ferroelectric film and an upper electrode film over the inter-layer insulator so as to be stacked in order;
etching the upper electrode film, the ferroelectric film and the lower electrode film so as to form a ferroelectric capacitor having a first side-wall; and
forming a hydrogen barrier film to cover the ferroelectric capacitor;
wherein the first side-wall of the lower electrode includes a tilt having an angle to a bottom surface of the lower electrode and at least a portion of the tilt is more gradual than the tilt of the first side-wall of the upper electrode and the ferroelectric film, the first side-wall of the ferroelectric film continuing into the first side-wall of the lower electrode.

15. The method for fabricating the semiconductor device having the ferroelectric memory cell according to claim 14, further comprising:
forming an etching mask on a formation region of the upper electrode between forming the lower electrode film, the ferroelectric film and the upper electrode film so as to be stacked in order, and forming the ferroelectric capacitor by etching.

16. The method for fabricating the semiconductor device having the ferroelectric memory cell according to claim 14,
wherein the hydrogen barrier film includes the oxide film.

17. The method for fabricating the semiconductor device having the ferroelectric capacitor according to claim 14,
wherein a pair of the two ferroelectric capacitors is formed, each of the two ferroelectric capacitors is in parallel each other to a gate width direction, each outer side-wall of the two ferroelectric capacitors is the first side-wall, each opposed side-wall of the two ferroelectric capacitors is a second side-wall, each second side-wall of the upper electrode and the ferroelectric film has a tilt and is separated by a groove, respectively, in the forming the ferroelectric capacitor.

18. A method for fabricating a semiconductor device having a ferroelectric memory cell, comprising:
forming a transistor having a diffusion layer on a semiconductor substrate;
forming an inter-layer insulator over the semiconductor substrate to cover the transistor;
forming a contact plug connecting to the diffusion layer;
forming a lower electrode film connecting to the contact plug, a ferroelectric film and an upper electrode film over the inter-layer insulator so as to be stacked in order;
forming an etching mask on a formation region of the upper electrode;
etching the upper electrode film or the upper electrode film and the ferroelectric film by using the etching mask;
forming a side-wall mask;
etching back the side-wall mask so as to form the side-wall mask at least on the side-wall of the upper electrode;
etching the ferroelectric film and the lower electrode film by using the side-wall mask so as to form a ferroelectric capacitor having a first side-wall;
forming a hydrogen barrier film to cover the ferroelectric capacitor;
wherein the first side-wall of the lower electrode includes a tilt having an angle to a bottom surface of the lower electrode and at least a portion of the tilt is more gradual than the tilt of the first side-wall of the upper electrode and the ferroelectric film, the first side-wall of the ferroelectric film continuing into the first side-wall of the lower electrode.

19. The method for fabricating the semiconductor device having the ferroelectric memory cell according to claim 18,
wherein the hydrogen barrier film includes the oxide film.

20. The method for fabricating the semiconductor device having the ferroelectric capacitor according to claim 18,
wherein a pair of the two ferroelectric capacitors is formed, each of the two ferroelectric capacitors is in parallel each other to a gate width direction, each outer side-wall of the two ferroelectric capacitors is the first side-wall, each opposed side-wall of the two ferroelectric capacitors is a second side-wall, each second side-wall of the upper electrode and the ferroelectric film has a tilt and is separated by a groove, respectively, in the forming the ferroelectric capacitor.
